(19) United States
(12) Patent Application Publication
(10) Pub. No.: US 2024/0331980 A1
(43) Pub. Date: Oct. 3, 2024

(54) PLASMA SOURCE

(71) Applicant: NISSIN ION EQUIPMENT CO., LTD., Koka-city (JP)

(72) Inventors: Honoka WATANABE, Koka-city (JP); Hideki Fujita, Koka-city (JP); Yuya Hirai, Koka-city (JP)

(73) Assignee: NISSIN ION EQUIPMENT CO., LTD., Koka-city (JP)

(21) Appl. No.: 18/471,914

(22) Filed: Sep. 21, 2023

(30) Foreign Application Priority Data
Mar. 27, 2023 (JP) 2023-050019

(51) Int. Cl. H01J 37/32

(52) U.S. Cl. CPC H01J 37/3244; H01J 37/32458; H01J 37/32532; H01J 37/32669; H01J 2237/33

(57) ABSTRACT

A plasma source includes a chamber in which plasma is generated, a cathode provided in the chamber that emits electrons into the chamber, and an electromagnet provided around the chamber. The electromagnet includes a coil and magnetic flux passing members that cause a magnetic flux generated by energization of the coil to reach the inside of the chamber. A usage mode of one or more of the magnetic flux passing members is changeable.

### CROSS-REFERENCE TO RELATED APPLICATION

This application claims priority from Japanese Patent Application No. JP 2023-050019, filed in the Japanese Patent Office on Mar. 27, 2023, the disclosure of which being incorporated by reference herein in its entirety.

### BACKGROUND

### 1. Field

Various embodiments are related to a plasma source.

### 2. Description of Related Art

An example of a plasma source is an ion source used in an ion implantation apparatus in which a plasma is generated and from which an ion beam is extracted. A direction of electrons emitted from the plasma source may be changed by a magnetic flux.

### SUMMARY

It is an aspect to adjust the direction of a magnetic flux passing through a chamber.

According to an aspect of one or more embodiments, there is provided a plasma source comprising a chamber in which plasma is generated; a cathode provided in the chamber that emits electrons into the chamber; and an electromagnet provided around the chamber. The electromagnet comprises a coil and a plurality of magnetic flux passing members configured to cause a magnetic flux generated by energization of the coil to reach the inside of the chamber, wherein a usage mode of at least one of the magnetic flux passing members is changeable.

According to an aspect of one or more embodiments, there is provided a plasma source comprising a chamber in which plasma is generated; a cathode that emits electrons into the chamber; and an electromagnet comprising a first yoke component; a second yoke component; a third yoke component connecting the first yoke component to the second yoke component; and a coil disposed on at least one of the first yoke component, the second yoke component and the third yoke component, wherein the first yoke component is disposed on a first side of the chamber and extends perpendicular to the third yoke component, the second yoke component is disposed on a second side of the chamber and extends perpendicular to the third yoke component, and a first length from a base end portion to a tip portion of the first yoke component is longer than a second length from a base end portion to a tip portion of the second yoke component, and the first length is changeable with respect to the second length.

According to an aspect of one or more embodiments, there is provided a plasma source comprising a chamber in which plasma is generated; a cathode that emits electrons into the chamber; and an electromagnet comprising a first yoke component; a second yoke component; a third yoke component connecting the first yoke component to the second yoke component; and a coil disposed on at least one of the first yoke component, the second yoke component and the third yoke component, wherein the first yoke component is disposed on a first side of the chamber and extends perpendicular to the third yoke component, the second yoke component is disposed on a second side of the chamber and extends perpendicular to the third yoke component, and a first length from a base end portion to a tip portion of the first yoke component is longer than a second length from a base end portion to a tip portion of the second yoke component.

### BRIEF DESCRIPTION OF DRAWINGS

The above and/or other aspects will become apparent and more readily appreciated from the following description of example embodiments, taken in conjunction with the accompanying drawings of which:

FIG. 1 is a schematic view showing an example of a configuration of a plasma source, according to an embodiment;

FIG. 2 is a schematic view showing a more detailed example of the plasma source of FIG. 1, according to an embodiment;

FIG. 3 is a schematic view showing an example of the magnetic pole member, according to an embodiment;

FIG. 4 is a schematic view showing an example of an electromagnet and its periphery, according to an embodiment;

FIG. 5 is a schematic view showing an example of an electromagnet and its periphery, according to an embodiment; and

FIG. 6 is a schematic view showing an example of an electromagnet and its periphery, according to an embodiment.

### DETAILED DESCRIPTION

Plasma ion sources generally include a chamber in which the plasma is generated and a cathode disposed within the chamber for emitting electrons. In such an ion source, electrons emitted from a cathode ionize a raw material gas supplied into a chamber to generate plasma, and an ion beam is extracted from the chamber.

Such an ion source may further include a reflector disposed to face the cathode. In the ion source having such a configuration, the electrons emitted from the cathode are directed toward the reflector by passing a magnetic flux through the chamber using an electromagnet provided around the chamber.

Since the direction of the magnetic flux passing through the chamber is determined, when a large number of electrons emitted from the cathode and ions in the plasma captured by the magnetic flux hit the central portion of the reflector, the central portion of the reflector is locally consumed.

In addition, when a large number of electrons or ions impinge on, for example, a portion deviated from the center of the reflector, the deviated portion is locally consumed. That is, the entire reflector was not uniformly consumed.

As another configuration of the ion source, there is a configuration in which a sputtering target is disposed to face the cathode. Also in such an ion source, the sputter target is locally consumed. That is, the entire sputtering target was not uniformly consumed.

Various embodiments herein are directed to adjusting the direction of the magnetic flux passing through the chamber to provide more uniform consumption of a reflector or a sputtering target.

Hereinafter, various embodiments of a plasma source are disclosed with reference to the drawings.

The plasma source of the various embodiments is an ion source constituting an ion beam irradiation apparatus such as an ion implantation apparatus, and generates an ion beam containing predetermined ions. The plasma source according to various embodiments is not limited to a plasma source used in an ion beam irradiation apparatus and, in some embodiments, may be a plasma source used in a plasma irradiation apparatus.

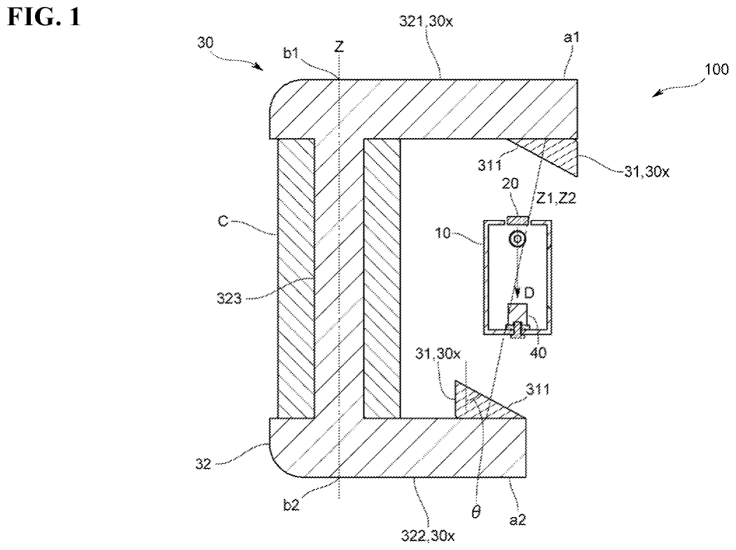

FIG. 1 is a schematic view showing an example of a configuration of a plasma source, according to an embodiment. As shown in FIG. 1, a plasma source 100 may include a chamber 10 in which plasma is generated, a cathode 20 that emits electrons into the chamber 10, and an electromagnet 30 that generates a magnetic flux that passes through the chamber 10. The plasma source 100 may further include a target 40 which is sputtered by ions and electrons in the chamber 10 to emit predetermined ions. As a more specific embodiment of the plasma source 100, an embodiment in which an ion beam including aluminum ions is generated and the target 40 is formed of a material including aluminum is exemplified.

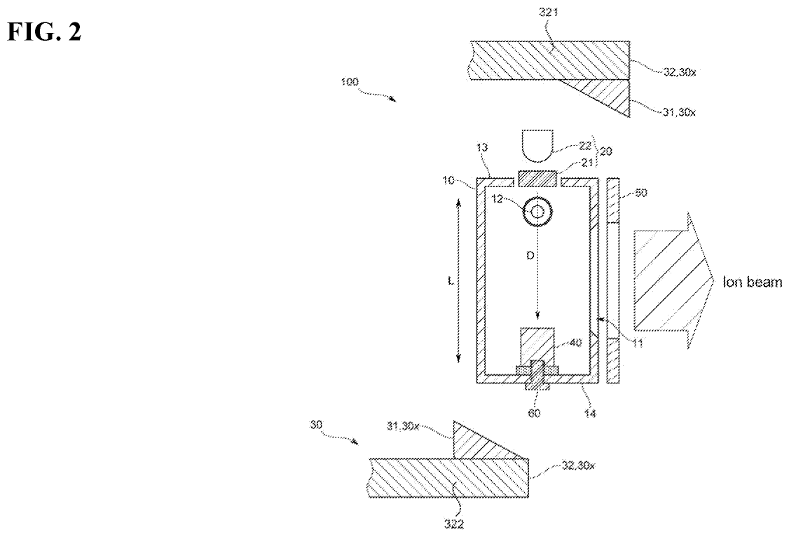

FIG. 2 is a schematic view showing a more detailed example of the plasma source of FIG. 1, according to an embodiment. As shown in FIG. 2, a beam extraction port 11 is formed on a surface of the chamber 10 facing an extraction electrode 50. The beam extraction port 11 has an elongated shape such as a rectangular shape, and the chamber 10 has an elongated shape such as a rectangular parallelepiped shape. A gas inlet 12 is formed in the chamber 10, and an ionized gas containing, for example, fluorine is introduced through the gas inlet 12.

The cathode 20 is provided on one end side in the longitudinal direction L of the chamber 10, and is provided on a side wall portion 13 (e.g., an upper wall portion in FIG. 2) on one end side in the longitudinal direction L of the chamber 10. The cathode 20 includes a cathode member 21 that emits thermal electrons into the chamber 10 by being heated, and a filament 22 that heats the cathode member 21.

As shown in FIG. 1, the electromagnet 30 is provided around the chamber 10 and generates a magnetic flux passing through the chamber 10. The electromagnet 30 has a coil C which is energized to generate a magnetomotive force, and a plurality of magnetic flux passing members 30x which allow a magnetic flux generated by energizing the coil to reach the inside of the chamber 10.

More specifically, the electromagnet 30 includes a pair (e.g., two in FIG. 1) of magnetic pole members 31 sandwiching the chamber 10, a yoke 32 holding the magnetic pole members 31 and provided around the chamber 10, and a coil C wound around the yoke 32. In some embodiments, each of the pair of magnetic pole members 31 and the yoke 32 may constitute a magnetic flux passing member 30x. That is, the pair of the magnetic pole members 31 are provided with one on each side of the chamber 10. One of the magnetic pole members 31 and a portion of the yolk 32 may correspond to a first magnetic flux passing member 30x, and the other of the magnetic pole members 31 and another portion of the yoke 32 may correspond to a second magnetic flux passing member 30x. As illustrated in the example of FIG. 1, the first magnetic flux passing member 30x may be provided at a top side of the chamber 10 and the second magnetic flux passing member 30x may be provided at a bottom side of the chamber 10. Since the plasma source 100 may be characterized by the electromagnet 30, the details thereof are disclosed below.

As shown in FIG. 2, the target 40 is disposed so as to face the cathode 20 in the chamber 10. The target 40 supplies, for example, aluminum ions into the chamber 10 by being sputtered by electrons emitted from the cathode 20 or ions (charged particles) in the plasma generated in the chamber 10. The shape of the target 40 is not limited to a specific shape. In some embodiments, the target 40 may have, for example, a rotating body shape. The rotating body shape is a shape of the target 40 in an unused state (a state before being sputtered).

The target 40 is provided on the other end side of the chamber 10 in the longitudinal direction L from the cathode 20, and is fixed to a side wall portion 14 (e.g., a lower wall portion in FIG. 2) on the other end side of the chamber 10 in the longitudinal direction using a fixing member 60 such as a screw.

The plasma source 100 causes electrons emitted from the cathode 20 and ions generated in the chamber 10 to travel toward a desired location on the surface of the target 40. When electrons or ions are caused to travel toward the central portion of the surface of the target 40, the aiming direction in which the electrons or ions are caused to travel is the facing direction D between the cathode 20 and a member disposed to face the cathode 20. That is, the electrons or ions are aimed in the facing direction D from the cathode 20 towards the target 40. On the other hand, when the electrons or ions are caused to travel toward the outside of the center portion of the surface of the target 40, the aiming direction in which the electrons or ions are caused to travel is a direction inclined with respect to the facing direction D.

The facing direction D is a main emission direction of electrons emitted from the cathode 20, and is a direction along the longitudinal direction L of the chamber 10 in the case in which the electrons or ions are caused to travel toward the central portion of the surface of the target 40.

The plasma source 100 is characterized in that a usage mode of the magnetic flux passing member 30x constituting the electromagnet 30 described above can be changed.

The usage mode of the magnetic flux passing member 30x is a concept indicating at least one of an orientation, a size, a position, and a presence or absence of the magnetic pole members 31. In other words, the plasma source 100 may be configured such that the orientation of the magnetic pole members 31 can be changed, the size of the magnetic pole members 31 can be changed, or the presence or absence of the magnetic pole members 31 can be changed.

More specifically, as disclosed above, the electromagnet 30 includes the pair of magnetic pole members 31, the yoke 32, and the coil C. As shown in FIG. 1, the yoke 32 has a first yoke component 321 provided with one magnetic pole member 31, a second yoke component 322 provided with the other magnetic pole member 31, and a third yoke component 323 which connects the first yoke component 321 and the second yoke component 322 and around which the coil C is wound.

In such a configuration, when the coil C is energized to generate a magnetomotive force, the magnetic flux generated by the third yoke component 323 reaches the chamber 10 via the first yoke component 321, the second yoke component 322, and the magnetic pole members 31. Therefore, in some embodiments, at least the first yoke component 321, the second yoke component 322, and the magnetic pole members 31 may constitute the magnetic flux passing member 30x.

At least one of the first yoke component 321, the second yoke component 322, and the magnetic pole member 31 is a magnetic flux passage member 30x configured to be changeable according to a use mode.

Hereinafter, for convenience of description, the yoke components 321 to 323 will be described, and then the magnetic pole member 31 will be described.

As shown in FIG. 1, the first yoke component 321 extends in a direction orthogonal to the opposing direction D, and one of the magnetic pole members 31 is attached to a tip portion a1 thereof.

The second yoke component 322 extends in parallel with the first yoke component 321, and the other magnetic pole member 31 is attached to the a2 of the tip portion thereof.

The third yoke component 323 extends parallel to the opposing direction D and connects a base end portion b1 of the first yoke component 321 and a base end portion b2 of the second yoke component 322.

Note that the first yoke component 321, the second yoke component 322, and the third yoke component 323 may be integrally provided. However, in some embodiments, some or all of the first yoke component 321, the second yoke component 322, and the third yoke component 323 may be separate bodies.

As shown in FIG. 1, assuming a reference imaginary line Z passing through the third yoke component 323 and extending along the central axes of the coil C, the length from the reference imaginary line Z to the tip a1 of the first yoke component 321 and the length from the reference imaginary line Z to the tip a2 of the second yoke component 322 are different from each other. For example, the reference imaginary line Z may pass through the proximal end b1 of the first yoke component 321 and the proximal end b2 of the second yoke component 322.

Here, the tip portion a1 of the first yoke component 321 is located on a side farther from the chamber 10 with respect to the reference virtual line Z, and the tip portion a2 of the second yoke component 322 is located on a side closer to the chamber 10 with respect to the reference virtual line Z.

That is, the tip portion a1 of the first yoke component 321 and the tip portion a2 of the second yoke component 322 are provided at different distances from the reference imaginary line Z in the direction orthogonal to the opposing direction e. Here, the distance from the reference imaginary line Z to the tip portion a1 is longer than the distance from the reference imaginary line Z to the tip portion a2.

According to the above-described configuration, a first imaginary line Z1 connecting the tip portion a1 of the first yoke component 321 and the tip portion a2 of the second yoke component 322 passes through the chamber 10 and is inclined with respect to the facing direction D.

One or both of the first yoke component 321 and the second yoke component 322 may be configured such that the lengths from the base end portions b1 and b2 to the tip end portions a1 and a2, in other words, the lengths from the reference imaginary line Z to the tip end portions a1 and a2 can be changed.

More specifically, in some embodiments, an entirety of one or both of the first yoke component 321 and the second yoke component 322 may be detachably provided to the third yoke component 323.

According to the above-described configuration, yoke components having different lengths from the base end portions to the tip end portions thereof may be prepared in advance, yoke component, and one or both of the first yoke component 321 and the second yoke component 322 to be attached to the third yoke component 323 may be selected from the prepared yoke components, whereby the length from the base end portions b1 and b2 to the tip end portions a1 and a2 of one or both of the first yoke component 321 and the second yoke component 322 can be changed.

In some embodiments, one or both of the first yoke component 321 and the second yoke component 322 may be formed of a plurality of magnetic bodies (here, soft iron) detachably arranged from the proximal end portions b1 and b2 toward the distal end portions a1 and a2, in other words, the arrangement number of the magnetic bodies may be changeable.

With this configuration, in one or both of the first yoke component 321 and the second yoke component 322, the length from the base end portions b1 and b2 to the tip end portions a1 and a2 can be changed in a stepwise manner by changing the number of arranged magnetic bodies.

Next, the magnetic pole member 31 will be described.

As shown in FIGS. 1 and 2, the pair of magnetic pole members 31 are provided at positions sandwiching the chamber 10. Specifically, one magnetic pole member 31 is provided on the cathode 20 side, and the other magnetic pole member 31 is provided on the side opposite to the cathode 20.

In some embodiments, the magnetic pole members 31 ma be separate members from the yoke 32, and may be magnetic bodies made of soft iron or the like, which is the same material as the yoke 32. However, in some embodiments, the magnetic pole member 31 may be provided integrally with the yoke 32 or may be a magnetic body (for example, a permanent magnet) made of a material different from that of the yoke 32.

In some embodiments, as described above, the tip portion a1 of the first yoke component 321 and the tip portion a2 of the second yoke component 322 may be provided at different distances from the reference virtual line Z in the direction orthogonal to the reference virtual line Z, and the magnetic pole members 31 are provided at the tip portions a1 and a2 of the first yoke component 321 and the second yoke component 322, respectively. Therefore, as illustrated in FIG. 1, a second virtual line Z2 connecting one magnetic pole member 31 and the other magnetic pole member 31 may pass through the chamber 10 and is inclined with respect to the facing direction D.

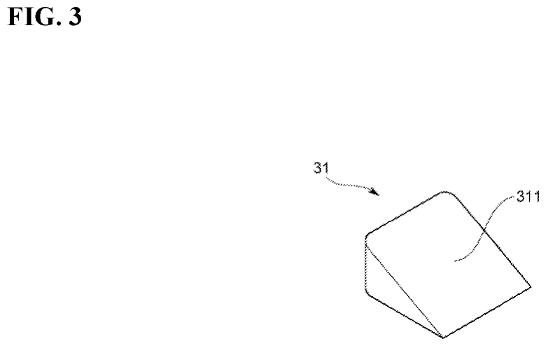

As shown in FIGS. 2 and 3, each magnetic pole member 31 may have, for example, a quadrangular or circular cross section and may have a shape obtained by cutting out a columnar magnetic body with an inclined surface that is inclined with respect to a central axis of the magnetic pole member 31 such that the magnetic pole member 31 has an end surface 311, and in this case, the magnetic pole member 31 may be disposed such that the end surface 311 faces the chamber 10.

That is, the end surface 311 of the magnetic pole member 31 facing the chamber 10 is inclined with respect to the facing direction D, and an angle θ formed between the inclined surface and the facing direction D is changeable.

More specifically, one magnetic pole member 31 may be detachably provided to the first yoke component 321, and the other magnetic pole member 31 may be detachably provided to the second yoke component 322.

By preparing a plurality of magnetic pole members 31 having different inclinations of the end face 311 and selecting the magnetic pole member 31 to be used from the prepared magnetic pole member 31, the angle θ formed by the end face 311 and the facing direction D can be changed.

Hereinafter, a method of using the plasma source 100 will be briefly described.

First, the plasma source 100 may be operated on the assumption that the magnetic flux passing through the chamber 10 is formed along the facing direction D. For example, due to various influences such as a magnetic field or heat from the outside of the chamber 10, the direction of the magnetic flux passing through the chamber 10 may be deviated from an assumed direction. That is, even when the plasma source 100 is operated on the assumption that the magnetic flux passing through the chamber 10 is formed along the facing direction D, the vicinity of the center of the target 40 is not necessarily locally consumed. The plasma source 100 may be operated by an operator, or may be operated by a controller that controls an operation of the plasma source 100.

Thereafter, the consumed portion of the target 40 is checked. For example, the operator may check the consumed portion of the target 40, or a sensor may be used to check the consumed portion of the target 40. Then, if the consumable portions are unevenly consumed on the surfaces of the targets 40, the usage mode of the one or more magnetic flux passing members 30x may be changed so that the magnetic flux is directed to the portion with the least consumption. Thus, such changes may result in more uniform wear of the target 40. For example, in some embodiments, a controller may indicate that the consumable portion of the target is being unevenly consumed and transmit or display a notification to change a usage mode.

According to the plasma source 100 configured as described above, since the usage mode of the magnetic flux passing member 30x constituting the electromagnet 30 can be changed, the direction of the magnetic flux passing through the chamber 10 can be changed accordingly. As a result, the direction in which the electrons emitted from the cathode 20 travel, the direction in which the ions in the plasma travel, or the plasma distribution can be adjusted, and the target 40 disposed to face the cathode 20 can be prevented from being locally consumed and thus can be consumed more evenly.

Since the usage mode of the first yoke component 321, the second yoke component 322, and the magnetic pole member 31, which may constitute the magnetic flux passing member 30x, can be changed, the magnetic flux passing through the chamber can be changed in various directions, and the direction in which the electrons emitted from the cathode travel, the direction in which the ions in the plasma travel, or the plasma distribution can be adjusted more freely.

Since the end surfaces 311 of the pair of magnetic pole members 31 are inclined with respect to the opposing direction D, the direction in which the magnetic flux formed by these magnetic pole members 31 passes can be inclined with respect to the opposing direction D.

This configuration makes it possible to adjust the direction in which the electrons emitted from the cathode 20 travel, the direction in which the ions in the plasma travel, or the plasma distribution so that the target portion on the surface of the target 40 is consumed.

Since the length from the base end portion b1 to the tip end portion a1 of the first yoke component 321 and the length from the base end portion b2 to the tip end portion a2 of the second yoke component 322 are different from each other and the magnetic pole members 31 are provided at the tip end portions a1 and a2 of the first yoke component 321 and the second yoke component 322, the magnetic pole facing direction which is a facing direction of the magnetic pole members 31 can be inclined with respect to the facing direction D.

Accordingly, as described above, it is possible to adjust the traveling direction of the electrons emitted from the cathode 20, the traveling direction of the ions in the plasma, or the plasma distribution so that the target portion on the surface of the target 40 is consumed more evenly and completely.

Since the first yoke component 321 and the second yoke component 322 are configured such that the lengths from the base end portions b1 and b2 to the tip end portions a1 and a2 can be changed, the direction of the magnetic flux passing through the chamber 10 can be changed by changing the length of the first yoke component 321 or the second yoke component 322, and it is easy to adjust the traveling direction of the electrons emitted from the cathode, the traveling direction of the ions in the plasma, or the plasma distribution.

However, embodiments are not limited to the above-described embodiment.

For example, in some embodiments, when the magnetic pole member 31 having the end surface 311 inclined with respect to the opposing direction D is provided, the length from the reference imaginary line Z to the tip portion a1 of the first yoke component 321 and the length from the reference imaginary line Z to the tip portion a2 of the second yoke component 322 may be equal to each other.

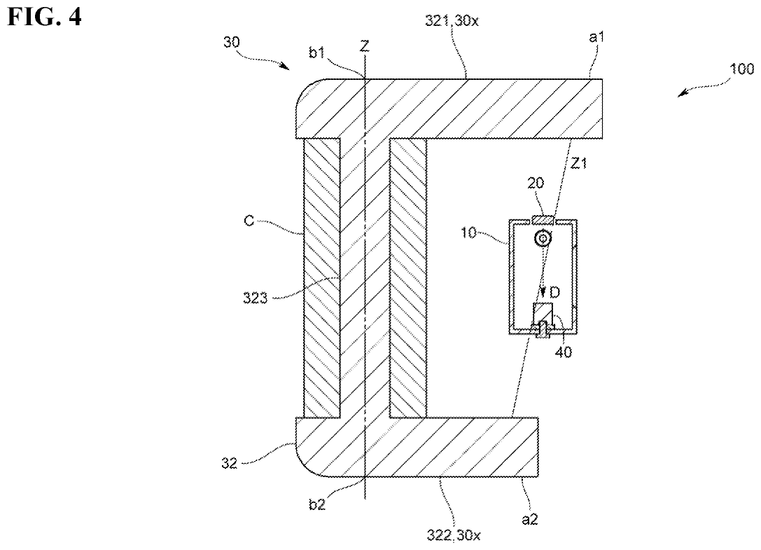

Further, as shown in FIG. 4, if the length from the reference imaginary line Z to the tip portion a1 of the first yoke component 321 and the length from the reference imaginary line Z to the tip portion a2 of the second yoke component 322 are different from each other, in some embodiments, the magnetic pole member 31 may be omitted.

Furthermore, although the magnetic pole member 31 has the end face 311 inclined with respect to the opposing direction D as described above, in some embodiments, the tip portions a1 and a2 of one or both of the first yoke component 321 and the second yoke component 322 may have an end face inclined with respect to the opposing direction D.

In some embodiments, only one magnetic pole member 31 of the pair of magnetic pole members 31 may be attachable to and detachable from the yoke 32. In some embodiments, each of the pair of magnetic pole members 31 may be integrally provided with the yoke 32 and may not be attachable to and detachable from the yoke 32.

In some embodiments, one or both of the pair of magnetic pole members 31 may be rotatable so that the inclination of the facing surface with respect to the facing direction D changes.

According to such a configuration, since the direction of the magnetic flux passing through the chamber 10 can be changed by rotating the magnetic pole member 31, the adjustment work of the traveling direction of the electrons is easy.

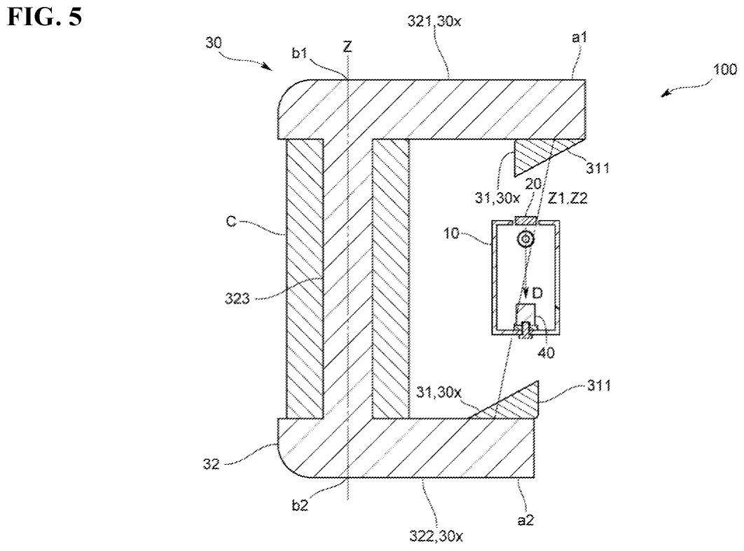

Although the pair of magnetic pole members 31 are provided so that the respective end surfaces 311 face each other as described above, in some embodiments, the pair of magnetic pole members 31 may be provided so that the respective end surfaces 311 face in opposite directions as shown in FIG. 5.

In some embodiments, the coil C may be wound around the first yoke component 321 or the second yoke component 322, or may be wound around a yoke component provided separately from the first to third yoke components 321, 322, to 323.

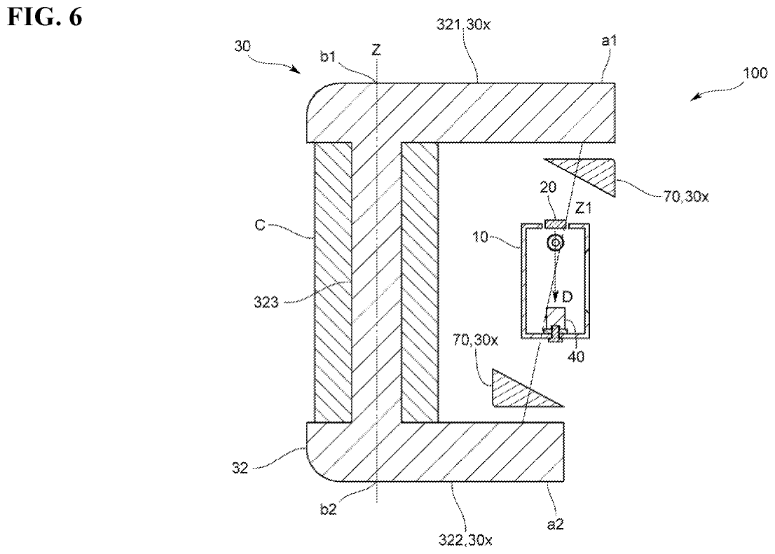

As described above, a case where the usage mode of the magnetic flux passing member 30x is changeable has been described, but embodiments are not limited thereto. For example, as shown in FIG. 6, a second magnetic flux passing member 70 through which a magnetic flux different from a magnetic flux of the electromagnet 30 passes may be used as the magnetic flux passing member 30x.

The second magnetic flux passing member 70 allows the magnetic flux generated in the third yoke component 323 by the magnetomotive force of the coil C to reach the inside of the chamber 10, and a usage mode of the second magnetic flux passing member 70 can be changed. In this case, the mode of use of the magnetic flux passing member 30x constituting the electromagnet 30 may be changeable or unchangeable.

Even with such a configuration, the direction of the magnetic flux passing through the chamber 10 can be changed by changing the usage mode of the second magnetic flux passing member 70. As a result, the traveling direction of the electrons emitted from the cathode 20 can be adjusted to be directed to, for example, the central portion of the target 40, and the target 40 can be prevented from being locally consumed and may be consumed more evenly.

In some embodiments, the plasma source 100 may omit the target 40 that is disposed to face the cathode 20. In some embodiments, the plasma source 100 may include, for example, a reflector that is disposed to face the cathode 20 and reflects electrons emitted from the cathode 20.

Embodiments are not limited to the above-described embodiments, and various modifications can be made without departing from the spirit and scope of the appended claims.

1. A plasma source comprising:
a chamber in which plasma is generated;
a cathode provided in the chamber that emits electrons into the chamber; and
an electromagnet provided around the chamber, the electromagnet comprising:
a coil; and
a plurality of magnetic flux passing members configured to cause a magnetic flux generated by energization of the coil to reach the inside of the chamber,
wherein a usage mode of at least one of the magnetic flux passing members is changeable.

2. The plasma source according to claim 1, wherein the usage mode is an orientation, a size, a position, or a presence or absence of the magnetic flux passing members.

3. The plasma source according to claim 1, wherein the plurality of magnetic flux passing members comprise:
a pair of magnetic pole members provided on a first side of the cathode and a second side of the cathode that is opposite to the first side of the cathode, respectively, and the pair of magnetic pole members sandwiching the chamber therebetween,
wherein an end surface of one or both of the pair of magnetic pole members that faces the chamber is inclined with respect to a facing direction from the cathode to a member disposed to face the cathode face each other.

4. The plasma source according to claim 3, wherein one or both of the pair of magnetic pole members are rotatable so that an inclination of the end surface with respect to the facing direction changes.

5. The plasma source according to claim 3, wherein the plurality of magnetic flux passing members comprise:
a first yoke component provided with one of the pair of magnetic pole members at a distal end portion thereof; and
a second yoke component provided with the other of the pair of magnetic pole members at a distal end portion thereof;
a third yoke component which connects a base end portion of the first yoke component and a base end portion of the second yoke component and around which the coil is wound, and
wherein a first length from a proximal end portion to the distal end portion of the first yoke component is different from a second length from a proximal end portion to the distal end portion of the second yoke component.

6. The plasma source according to claim 5, wherein one or both of the first length and the second length is changeable.

7. A plasma source comprising:
a chamber in which plasma is generated;
a cathode that emits electrons into the chamber; and
an electromagnet comprising:
a first yoke component;
a second yoke component;
a third yoke component connecting the first yoke component to the second yoke component; and
a coil disposed on at least one of the first yoke component, the second yoke component and the third yoke component,
wherein the first yoke component is disposed on a first side of the chamber and extends perpendicular to the third yoke component,
the second yoke component is disposed on a second side of the chamber and extends perpendicular to the third yoke component, and
a first length from a base end portion to a tip portion of the first yoke component is longer than a second length from a base end portion to a tip portion of the second yoke component, and the first length is changeable with respect to the second length.

8. The plasma source according to claim 7, wherein each of the first yoke component and the second yoke component comprises a plurality of magnetic bodies.

9. The plasma source according to claim 7, further comprising a first magnetic pole member provided at the tip portion of the first yoke component and a second magnetic pole member provided at the tip portion of the second yoke component.

10. The plasma source according to claim 9, wherein at least one of an orientation, a size, and a position of the first magnetic pole member and the second magnetic pole member may be changed.

11. The plasma source according to claim 10, wherein the electromagnet causes a magnetic flux generated by energization of the coil to reach inside of the chamber, and a change of the at least one of the orientation, the size, and the position of the first magnetic pole member and the second magnetic pole member changes a direction of the magnetic flux with respect to a direction parallel to the third yoke component.

12. The plasma source according to claim 9, wherein the first magnetic pole member is detachable from the first yoke component and the second magnetic pole member is detachable from the second yoke component.

13. The plasma source according to claim 9, wherein the first magnetic pole member has an inclined surface that faces the chamber and the second magnetic pole member has an inclined surface that faces the chamber.

14. The plasma source according to claim 13, wherein an inclination angle of the inclined surface of the first magnetic pole member and an inclination angle of the inclined surface of the second magnetic pole member are changeable.

15. The plasma source according to claim 13, wherein each of the inclined surface of the first magnetic pole member and the inclined surface of the second magnetic pole member is inclined with respect to a direction parallel to the third yoke component, and an angle formed between the inclined surface and the direction is changeable.

16. The plasma source according to claim 7, further comprising a first magnetic flux passing member provided between the tip portion of the first yoke component and the chamber, and a second magnetic flux passing member provided between the tip portion of the second yoke component and the chamber.

17. The plasma source according to claim 16, wherein the electromagnet causes a first magnetic flux generated by energization of the coil to reach an inside of the chamber, and
wherein the first magnetic flux passing member and the second magnetic flux passing member cause a second magnetic flux generated by the energization of the coil to reach the inside of the chamber, the second magnetic flux being different from the first magnetic flux.

18. A plasma source comprising:
a chamber in which plasma is generated;
a cathode that emits electrons into the chamber; and
an electromagnet comprising:
a first yoke component;
a second yoke component;
a third yoke component connecting the first yoke component to the second yoke component; and
a coil disposed on at least one of the first yoke component, the second yoke component and the third yoke component,
wherein the first yoke component is disposed on a first side of the chamber and extends perpendicular to the third yoke component,
the second yoke component is disposed on a second side of the chamber and extends perpendicular to the third yoke component, and
a first length from a base end portion to a tip portion of the first yoke component is longer than a second length from a base end portion to a tip portion of the second yoke component.

19. The plasma source according to claim 18, wherein each of the first yoke component and the second yoke component comprises a plurality of magnetic bodies.

20. The plasma source according to claim 18, further comprising a first magnetic pole member provided at the tip portion of the first yoke component and a second magnetic pole member provided at the tip portion of the second yoke component.
